(19) United States
(12) Patent Application Publication
(10) Pub. No.: US 2019/0371977 A1
(43) Pub. Date: Dec. 5, 2019

(54) LIGHTING SYSTEMS AND ASSOCIATED METHODS COMBINING VISIBLE AND NON-VISIBLE LIGHT CONVERTING PHOSPHOR

(71) Applicants: Tek Beng LOW, Melaka (MY); Eng Wah TAN, Melaka (MY); Chee Sheng LIM, Melaka (MY)

(72) Inventors: Tek Beng LOW, Melaka (MY); Eng Wah TAN, Melaka (MY); Chee Sheng LIM, Melaka (MY)

(21) Appl. No.: 16/541,584

(22) Filed: Aug. 15, 2019

Related U.S. Application Data
(63) Continuation-in-part of application No. 15/797,843, filed on Oct. 30, 2017.

(30) Foreign Application Priority Data
Oct. 25, 2017 (MY) PI2017704026

(51) Int. Cl. H01L 33/50

(52) U.S. Cl. CPC H01L 33/502

(57) ABSTRACT

A lighting system combining visible and non-visible light converting phosphor, wherein the lighting system includes: a light emitting diode (LED) package; at least one light emitting diode (LED) chip associated with the light emitting diode (LED) package; a phosphor material associated with at least a portion of the at least one light emitting diode (LED) chip, wherein the phosphor material includes: a first converting material that emits in the visible light spectrum; and a second converting material that emits in the non-visible light spectrum; and wherein the first converting material and the second converting material controllably regulate light output of the lighting system.

### CROSS-REFERENCE TO RELATED APPLICATIONS

This application is a continuation-in-part of U.S. application Ser. No. 15/797,843, entitled “LIGHTING SYSTEMS AND METHODS COMBINING VISIBLE AND NON-VISIBLE LIGHT CONVERTING PHOSPHOR” filed Oct. 30, 2017, which claims the benefit of Malaysian Patent Application Serial No. PI2017704026, filed Oct. 25, 2017—which are hereby incorporated herein by reference in their entirety, including all references cited therein.

### STATEMENT REGARDING FEDERALLY SPONSORED RESEARCH OR DEVELOPMENT

Not applicable.

### REFERENCE TO A SEQUENCE LISTING

Not applicable.

### BACKGROUND OF THE INVENTION

### 1. Field of the Invention

The present invention relates in general to lighting systems and, more particularly, to lighting systems that include a light emitting diode (LED) package, at least one light emitting diode (LED) chip associated with the light emitting diode (LED) package, a phosphor material associated with at least a portion of the at least one light emitting diode (LED) chip, wherein the phosphor material includes a first converting material and a second converting material that controllably regulate the light output of the lighting system.

### 2. Background Art

Generally, light emitting diodes (LEDs), are well known for a broad range of industrial applications, primarily due to multiple advantages of LEDs, including, but not limited to, energy efficiency, low power consumption, small size, durability, long life, cost-effective manufacturing, low heat generation, and the like.

During manufacturing and production of LEDs, LED manufacturers focus a majority of their efforts on the testing and quality control of LEDs. Consequently, it is common to sort the LEDs as per different criteria, such as, for example, color (wavelength), lumen output (brightness or intensity), forward voltage, and the like. This process of sorting the LEDs is generally known as binning and the criteria of binning is commonly known as binning parameters.

A main goal of LED manufacturers is to make the binning process more efficient and in most applications, multiple LEDs are used and placed side by side, for example, in a display panel. Accordingly, to ensure uniformity in the display panel, it is important that the LEDs from the same bins are utilized because LEDs from different bins will have different light output, thereby resulting in non-uniform appearance when placed side-by-side.

One of the challenges for LED manufacturers today is not to produce too many bins. However, this is typically unavoidable due to the variation in producing the LED chips and hence, it is not possible to produce perfectly similar chips without any variation in high volume.

Moreover, phosphor is used today as a converting material to produce white light in white LEDs. A typical white LED generally consists of a blue chip (which produces blue light) and phosphor, whereby the blue light from the blue LED converts the phosphor material into yellow light, whereby when combined produces the white light.

Accordingly, there exists a need in the art for lighting systems and methods of combining visible and non-visible light converting phosphor, to reduce the number of bins required and to add more efficiency to the LED manufacturing process.

By way of additional background, lighting systems have been known in the art for years, and are the subject of a plurality of patents including, for example: U.S. Pat. No. 9,905,736 entitled “White Light-Emitting Device with Sealing Resin Including a Plurality of Phosphors,” U.S. Pat. No. 8,890,403 entitled “White Light-Emitting Device and Illumination Device,” U.S. Pat. No. 8,685,762 entitled “Light Emitting Device and Display,” U.S. Pat. No. 7,943,941 entitled “Device for Emitting Various Colors,” U.S. Pat. No. 7,083,302 entitled “White Light LED Assembly,” U.S. Pat. No. 6,890,085 entitled “LED Module,” U.S. Pat. No. 6,762,551 entitled “White Light Source and Display Apparatus Using the Same,” United States Patent Application Publication Number 2016/0276549 entitled “Light Emitting Device and Illumination Device,” United States Patent Application Publication Number 2008/0180948 entitled “White Light Emitting Device and Light Source Module for Liquid Crystal Display Backlight Using the Same,” and International Patent Publication Number WO 2011/069177 entitled “Lighting Having LED”—all of which are hereby incorporated herein by reference in their entirety including all references cited therein.

U.S. Pat. No. 9,905,736 appears to disclose a white light-emitting device which includes a light-emitting element that emits a blue light, and a sealing resin that seals the light-emitting element and that includes a first phosphor and a second phosphor, the first phosphor wavelength-converting a portion of the blue light and emitting a red light, the second phosphor wavelength-converting a portion of the blue light and emitting a green light. The white light-emitting device emits a white light by mixing the blue, red and green lights. The sealing resin further includes a third phosphor that wavelength-converts a portion of the blue light, emits a light in a same color gamut as the first or second phosphor, and has a higher light conversion efficiency than the first or second phosphor. The third phosphor is included in the sealing resin at an additive amount less than an amount that causes a change in a spectrum of the white light.

U.S. Pat. No. 8,890,403 appears to provide a technology that allows reducing the used amount of a Mn⁴⁺-activated fluoride complex phosphor without loss of luminous efficiency, in a white light-emitting device that is provided with the Mn⁴⁺-activated fluoride complex phosphor and an LED element that is an excitation source of the phosphor. U.S. Pat. No. 8,890,403 further appears to disclose a white light-emitting device comprises that a blue LED element, as well as a yellow phosphor and/or a green phosphor and a red phosphor as phosphors that are excited by the blue LED element. The red phosphor contains a Mn⁴⁺-activated fluoride complex phosphor and a Eu²⁺-activated alkaline earth silicon nitride phosphor.

U.S. Pat. No. 8,685,762 appears to disclose a light emitting device that comprises: an LED chip having a quantum well structure and a light emitting layer made of a gallium nitride compound semiconductor; a first transparent material covering the LED chip; a second transparent material for protecting the LED chip and the first transparent material; and a phosphor for absorbing a part of the light from the LED chip and emitting a light having a wavelength different from the light from the LED chip; wherein the phosphor is included in second transparent material, and the light from the LED chip and the light from said phosphor are mixed to make a white light.

U.S. Pat. No. 7,943,941 appears to disclose a device for emitting various colors by mixing light from a first light emitting diode and light from a second light emitting diode that comprises: the first light emitting diode including an LED chip comprising InGaN and being capable of emitting a blue color light, and a phosphor capable of absorbing a part of the blue color light and emitting a yellow color light, the blue color light and the yellow color light being mixed to make white-color light; the second light emitting diode being capable of emitting red, green or blue color light; and a drive circuit for separately driving each of the first and second light emitting diodes.

U.S. Pat. No. 7,083,302 appears to disclose a white light LED assembly that has at least two kinds of light-emitting units. The units can be a white light-emitting unit composed of red, green and blue LEDs, a white light-emitting unit composed of a blue and yellowish-green LEDs, a white light-emitting unit composed of a blue LED and yellow phosphor, or a white light-emitting units composed of UV LED and red, green and blue phosphors. The white light LED assembly according to the present invention has satisfactory efficiency and color rendering property as well as flexible phosphor usage.

U.S. Pat. No. 6,890,085 appears to disclose an LED module for generating white light having a plurality of white-light LEDs including at least one LED with a central wavelength of between 495 nm and 507 nm, at least one LED with a central wavelength of between 511 nm and 529 nm, at least one LED with a central wavelength of between 586 nm and 602 nm, and at least one LED with a central wavelength of between 618 nm and 630 nm.

U.S. Pat. No. 6,762,551 appears to disclose a white light source that includes an ultraviolet-visible excitation light generation unit capable of generating visible light and ultraviolet light, and a fluorescence generation unit having a phosphor layer and being capable of generating visible light upon excitation by the ultraviolet light and uses, in the phosphor layer, a red light emitting phosphor represented by the following compositional formula: (Ca_{1-a-b}SrₐEu_{b})S:M_{c}, wherein a, b and c satisfy the following conditions: 0≤a<1.0, 0≤b<0.1 and 0≤c≤0.1; and M is a dopant element having absorption of excitation energy at about 350 nm to about 500 nm. The dopant element M includes rare earth elements such as Ce, Yb, Gd and Tm. By substituting part of Ca and/or Sr with Zn, the white light source can exhibit further improved performances. The white light source exhibits an increased red light component as compared with light emitted from conventional (Y_{1-a-b}GdₐCe_{b})₃(Al_{1-c}Ga_{c})₅O₁₂ green light phosphors.

United States Patent Application Publication Number 2016/0276549 appears to disclose a light emitting device which emits a secondary light with high color purity and has a fast response speed. A KSF phosphor which absorbs a part of blue light and emits red light and a CASN phosphor are distributed in a resin which seals an LED chip which emits the blue light. The KSF phosphor absorbs the blue light and emits the red light by forbidden transition, and the CASN phosphor absorbs the blue light and emits the red light by allowed transition.

United States Patent Application Publication Number 2008/0180948 appears to disclose a white light emitting device that includes: a blue LED chip having a dominant wavelength of 430 to 455 nm; a red phosphor disposed around the blue light emitting diode chip, the red phosphor excited by the blue light emitting diode chip to emit red light; and a green phosphor disposed around the blue light emitting diode chip, the green phosphor excited by the blue LED chip to emit green light, wherein the red light emitted from the red phosphor has a color coordinate falling within a space defined by four coordinate points (0.5448, 0.4544), (0.7079, 0.2920), (0.6427, 0.2905) and (0.4794, 0.4633) based on the CIE 1931 chromaticity diagram, the green light emitted from the green phosphor has a color coordinate falling within a space defined by four coordinate points (0.1270, 0.8037), (0.4117, 0.5861), (0.4197, 0.5316) and (0.2555, 0.5030) based on the CIE 1931 color chromaticity diagram, and the red phosphor includes a phosphor represented by (Sr, Ba, Ca)AlSiN₃:Eu and the green phosphor includes a phosphor represented by (Sr, Ba, Ca)₂SiO₄:Eu.

International Patent Publication Number WO 2011/069177 appears to disclose a lighting means, comprising at least one first light-emitting diode, which emits light in the blue to ultraviolet range, and comprising a first color conversion material, which converts at least part of the light emitted by the light-emitting diode into a light having a higher wavelength. The lighting means is characterized in that the first color conversion material converts at least a sub-range of the light emitted in the blue to ultraviolet range into light of a different wavelength or absorbs said sub-range to such an extent that light without harm to living beings is emitted.

While the above-identified patents do appear to disclose a plurality of lighting systems, their configurations remain non-desirous and/or problematic inasmuch as, among other things, none of the above-identified lighting systems appear to provide a lighting system that includes a light emitting diode (LED) package, at least one light emitting diode (LED) chip associated with the light emitting diode (LED) package, a phosphor material associated with at least a portion of the at least one light emitting diode (LED) chip, wherein the phosphor material includes a first converting material, and a second converting material that controllably regulate the light output of the lighting system.

These and other objects of the present invention will become apparent in light of the present specification, claims, and drawings.

### SUMMARY OF THE INVENTION

The present invention is directed to a lighting system combining visible and non-visible light converting phosphor, comprising, consisting essentially of, and/or consisting of: (a) a light emitting diode (LED) package; (b) at least one light emitting diode (LED) chip associated with the light emitting diode (LED) package; and (c) a phosphor material associated with at least a portion of the at least one light emitting diode (LED) chip, wherein the phosphor material comprises: (1) a first converting material, wherein the first converting material emits in the visible light spectrum; (2) a second converting material, wherein the second converting material emits in the non-visible light spectrum; and (3) wherein the first converting material and the second converting material controllably regulate light output of the lighting system.

In another preferred embodiment of the present invention, the first converting material is phosphor which emits in the visible light spectrum. In this embodiment, the first converting material comprises yttrium aluminum garnet that may optionally be doped with at least one of the group consisting of an alkali metal, an alkaline earth metal, a transition metal, a lanthanide, an actinide, and combinations thereof.

In yet another preferred embodiment of the present invention, the first converting material comprises lutetium aluminum garnet that may optionally be doped with at least one of the group consisting of an alkali metal, an alkaline earth metal, a transition metal, a lanthanide, an actinide, and combinations thereof.

In a preferred embodiment of the present invention, the first converting material may also comprise a nitride, such as an interstitial nitride, gallium nitride, and/or indium gallium nitride.

In another preferred embodiment of the present invention, the first converting material comprises a silicate, such as, but not limited to, europium doped silicate.

In a preferred embodiment of the present invention, the second converting material is phosphor which emits in the non-visible light spectrum.

In another preferred embodiment of the present invention, the second converting material comprises gadolinium gallium aluminum garnet.

In yet another preferred embodiment of the present invention, the second converting material comprises oxo(oxochromiooxy)chromium.

In one aspect of the present invention, the second converting material preferably comprises chromium(III) oxide.

In a preferred embodiment of the present invention, the second converting material comprises a combination of gadolinium gallium aluminum garnet and chromium(III) oxide. In this embodiment, the weight ratio of gadolinium gallium aluminum garnet to chromium(III) oxide ranges from approximately 99:1 to approximately 90:10.

In another preferred embodiment of the present invention, the ratio of Al³⁺ to Ga³⁺ in the gadolinium gallium aluminum garnet ranges from approximately 0.25:1 to approximately 0.95:1, and more preferably from approximately 0.5:1 to approximately 0.7:1.

In yet another preferred embodiment of the present invention, the at least one light emitting diode (LED) chip is a blue LED chip and/or a UV LED chip.

The present invention is also directed to a method for matching light output of a first lighting system and a second lighting system, comprising the steps of: (a) providing a first lighting system having a light output, said first lighting system comprising: (1) a light emitting diode (LED) package; (2) at least one light emitting diode (LED) chip associated with the light emitting diode (LED) package; and (3) a phosphor material associated with at least a portion of the at least one light emitting diode (LED) chip; (b) determining the light output of the first lighting system and establishing binning parameters; (c) providing a second lighting system having a light output, said second lighting system comprising: (1) a light emitting diode (LED) package; (2) at least one light emitting diode (LED) chip associated with the light emitting diode (LED) package; and (3) a phosphor material associated with at least a portion of the at least one light emitting diode (LED) chip, wherein the phosphor material comprises: (a) a first converting material, wherein the first converting material emits in the visible light spectrum; and (b) a second converting material, wherein the second converting material emits in the non-visible light spectrum; and (d) substantially matching the light output of the second lighting system to the light output of the first lighting system via the first and second converting materials of the second lighting system to comport with the established binning parameters.

### BRIEF DESCRIPTION OF THE DRAWINGS

Certain embodiments of the present invention are illustrated by the accompanying figures. It will be understood that the figures are not necessarily to scale and that details not necessary for an understanding of the invention or that render other details difficult to perceive may be omitted.

It will be further understood that the invention is not necessarily limited to the particular embodiments illustrated herein.

The invention will now be described with reference to the drawings wherein:

FIG. 1 illustrates a block diagram of a lighting system combining visible and non-visible light converting phosphor, in accordance with an embodiment of the present invention;

FIG. 2 illustrates a flow diagram of a method for manufacturing the lighting system combining visible and non-visible light converting phosphor, in accordance with an embodiment of the present invention;

FIG. 3 illustrates a block diagram of the lighting system combining visible and non-visible light converting phosphor, in accordance with multiple embodiments of the present invention; and

FIG. 4 illustrates a spectrum of light output consisting of both visible and non-visible range, in accordance with multiple embodiments of the present invention.

### DETAILED DESCRIPTION OF THE INVENTION

While this invention is susceptible of embodiment in many different forms, there is shown in the drawings and described herein in detail several specific embodiments with the understanding that the present disclosure is to be considered as an exemplification of the principles of the invention and is not intended to limit the invention to the embodiments illustrated.

It will be understood that like or analogous elements and/or components, referred to herein, may be identified throughout the drawings by like reference characters. In addition, it will be understood that the drawings are merely schematic representations of one or more embodiments of the invention, and some of the components may have been distorted from their actual scale for purposes of pictorial clarity.

Various embodiments of the present invention relate to lighting systems and methods combining visible and non-visible light converting phosphor, aimed at limiting the number of bins by combining visible light converting phosphor (the type of phosphor which converts visible light from one wave length or light output to another visible light of a different wavelength or light output) with non-visible light converting phosphor (the type of phosphor which converts visible light to non-visible wavelengths, like infrared or ultraviolet). Consequently, some of the visible light is converted to non-visible light range (e.g., heat).

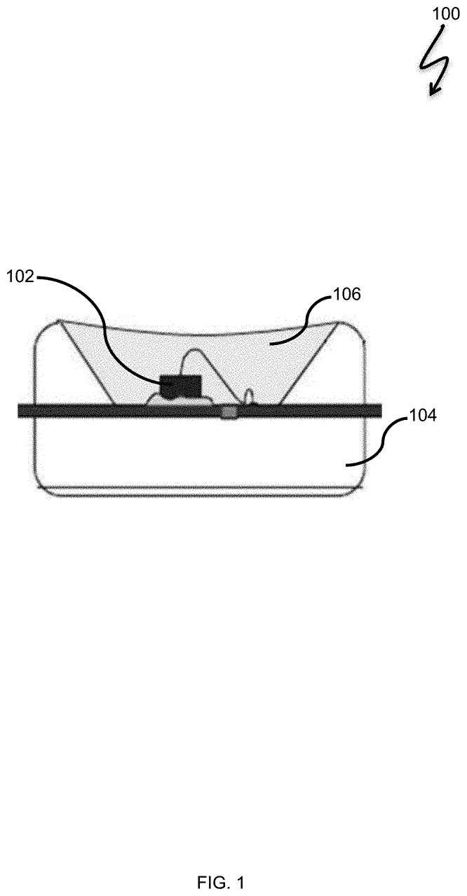

FIG. 1 illustrates a block diagram of a lighting system 100 combining visible and non-visible light converting phosphor. In accordance with an embodiment of the present invention, the lighting system 100 combining visible and non-visible light converting phosphor includes, a light emitting diode (LED) package 104, a light emitting diode (LED) chip 102 mounted on the light emitting diode (LED) package 104, a phosphor material 106 covering the light emitting diode (LED) chip 102. In use, the phosphor material 106 includes a first converting material and a second converting material.

In accordance with an embodiment of the present invention, the first converting material is phosphor which emits in the visible light spectrum and the second converting material is phosphor material that emits in the non-visible spectrum of light. Those of ordinary skill in the art will appreciate that the phosphor material can contain one or more than one phosphor types, as desired in a specific end use application of the invention. As used herein, “phosphor” refers to any material that converts the wavelengths of light irradiating it and/or that is fluorescent and/or phosphorescent and the specific components and/or formulation of the phosphor are not limitations of the present invention.

In one embodiment of the present invention, the first converting material preferably comprises yttrium aluminum garnet (e.g., Y₃,Al₅O₁₂) which may optionally be doped with alkali metal, an alkaline earth metal, a transition metal, a lanthanide, and/or an actinide (e.g., Y₃₋ₓAl_{5-y}D_{(x,y)}O₁₂, wherein D is a dopant and wherein x and y are the same or different dopant).

In another embodiment of the present invention, the first converting material preferably comprises lutetium aluminum garnet (e.g., Al₅Lu₃O₁₂) which may optionally be doped with alkali metal, an alkaline earth metal, a transition metal, a lanthanide, and/or an actinide (e.g., Al₅₋ₓLu_{3-y}D_{(x,y)}O₁₂, wherein D is a dopant and wherein x and y are the same or different dopant).

In yet another embodiment of the present invention, the first converting material preferably comprises a nitride, such as, but not limited to, interstitial nitride, gallium nitride (e.g., GaN), and/or indium gallium nitride (e.g., InGaN, InₓGa₁₋ₓN).

The first converting material of the present invention may also comprise a silicate, such as europium doped silicate.

It will be understood that, unless otherwise specified, the first converting materials provided herein, or their precursors, are available from commercial chemical vendors, such as Sigma-Aldrich Chemical Co., of St. Louis, Mo.

In a preferred embodiment of the present invention, the second converting material preferably comprises gadolinium gallium aluminum garnet (e.g., Gd₃,Ga₅₋ₓ,AlₓO₁₂).

In another preferred embodiment of the present invention, the second converting material preferably comprises oxo(oxochromiooxy)chromium and/or chromium(III) oxide (e.g., Cr₂O₃).

In yet another preferred embodiment of the present invention, the second converting material comprises a combination of gadolinium gallium aluminum garnet and chromium(III) oxide, wherein the weight ratio of gadolinium gallium aluminum garnet to chromium(III) oxide ranges from approximately 99:1 to approximately 90:10. In this embodiment, the ratio of Al³⁺ to Ga³⁺ in the gadolinium gallium aluminum garnet preferably ranges from approximately 0.25:1 to approximately 0.95:1, and more preferably ranges from approximately 0.5:1 to approximately 0.7:1.

It will be understood that, unless otherwise specified, the second converting materials provided herein, or their precursors, are available from commercial chemical vendors, such as Sigma-Aldrich Chemical Co., of St. Louis, Mo.

In a preferred embodiment of the present invention, the weight ratio of the first converting material to the second converting material preferably ranges from approximately 50:1 to approximately 2:1, and more preferably ranges from approximately 25:1 to approximately 5:1.

In accordance with an embodiment of the present invention, the light emitting diode (LED) chip 102 is a blue LED chip and/or a UV LED chip. In use, the light emitting diode (LED) chips 102 belong to one or more LED bins. Generally, the LED bins have a corresponding light output performance with respect to a light wavelength and/or light brightness, and/or other similar parameters. Those of ordinary skills in the art will appreciate that the combination of the first converting material and the second converting material provides one or more characteristics to the system 100. In use, such characteristics are dependent upon the first converting material that converts light in visible spectrum, and the second converting material that converts light in non-visible spectrum, as explained hereinabove.

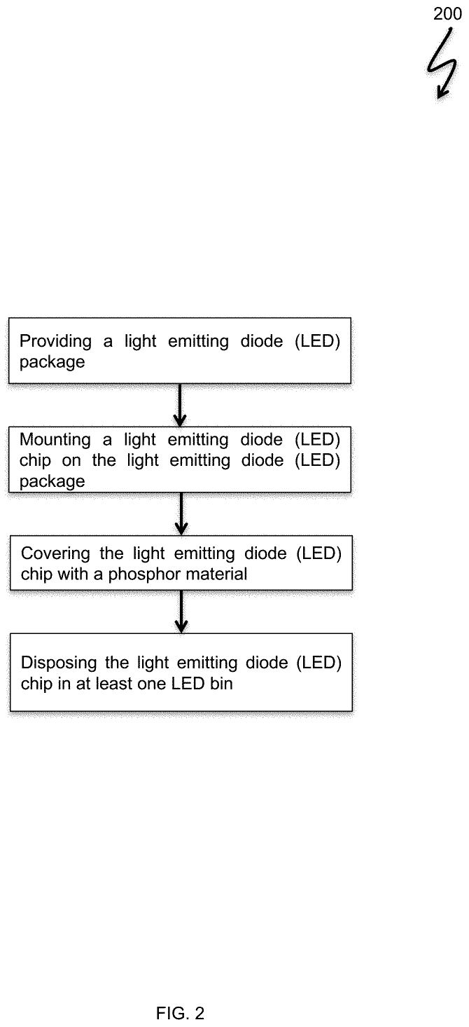

FIG. 2 illustrates a flow diagram of a method 200 for manufacturing the lighting system combining visible and non-visible light converting phosphor. In accordance with an embodiment of the present invention, the method 200 of manufacturing a lighting system combining visible and non-visible light converting phosphor, includes the steps of, providing a light emitting diode (LED) package; mounting at least one light emitting diode (LED) chip on the light emitting diode (LED) package; and, covering the at least one light emitting diode (LED) chip with a phosphor material. In use, the phosphor material includes a first converting material and a second converting material, and the spectral appearance of the lighting system is dependent upon a combination of the first converting material and the second converting material.

In accordance with an embodiment of the present invention, the method 200 further includes disposing the light emitting diode (LED) chip in at least one LED bin, as discussed above.

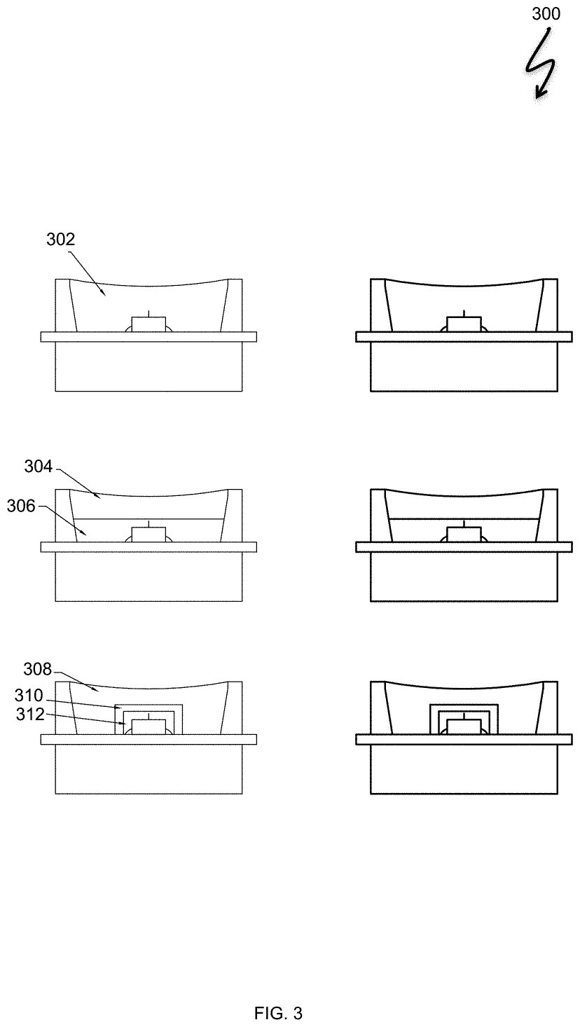

FIG. 3 illustrates a block diagram of the lighting system 300 combining visible and non-visible light converting phosphor, in accordance with multiple embodiments of the present invention. As seen therein, material 302 refers to a combination of non-visible light converting phosphor material and visible light converting phosphor material. Additionally, material 304 refers to visible light converting phosphor material and material 306 refers to non-visible light converting phosphor material. Also, material 308 refers to clear material, 310 refers to visible light converting phosphor material and 312 refers to non-visible light converting phosphor material. Consequently, as may be seen, different types of materials may be employed for multiple embodiments as disclosed herein.

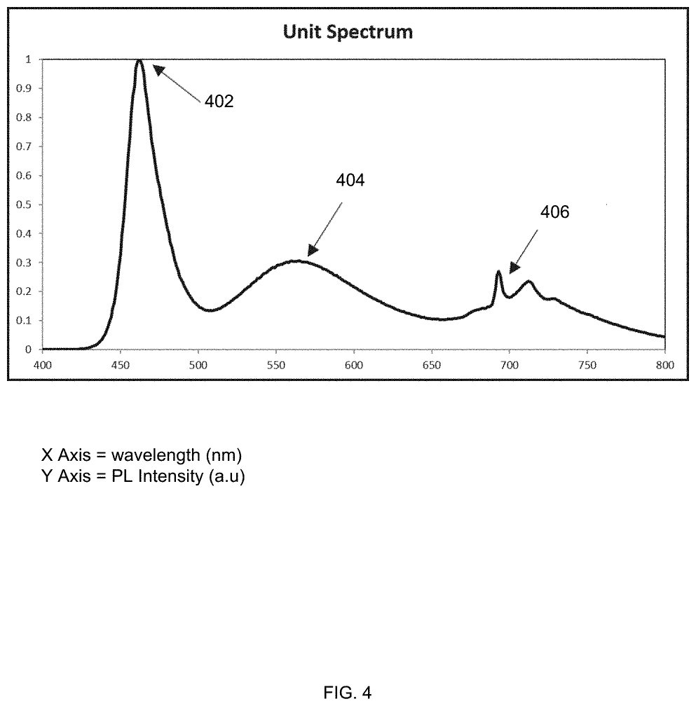

Those of ordinary skill in the art will appreciate that the first converting material includes a generic material that absorbs light of a shorter wavelength from the LED chip and converts it into polychromatic light with longer wavelengths in the visible wavelength range. In use, the typical visible range output is from 480 nm to 650 nm. In addition, the second material absorbs light of a shorter wavelength from the LED chip and converts it into light with longer wavelength in the non-visible wavelength range or greater than 680 nm. FIG. 4 illustrates a spectrum of the light output consisting of both the visible and non-visible range. As illustrated therein, 402 represents the LED, 404 represents visible light converting phosphor material and 406 represents non-visible light converting phosphor material.

Subsequently, the first converting material allows the flexibility to vary the quantity of converting material used to derive the desired color. In use, the second converting material is used to absorb the light from the LED chip for converting it to light in the non-visible range, and, in turn, reduces the total visible light to the eye. As a result, the converted non-visible light does not influence the visible color and hence it is convenient to be used as a means to vary and control the total visible light output.

Furthermore, for practical applications, LED chips with higher light output (or higher optical power) are mixed with more quantity of the second converting material to reduce the total visible light output. Similarly, LED chips with lower light output (or lower optical power) are mixed with lower quantity or may even be employed without the second converting material. Consequently, with such control, the range of visible light output or the number of bins can be reduced as disclosed herein.

Therefore, as may be seen, various embodiments of the present invention disclose lighting systems and methods combining visible and non-visible light converting phosphor, which provide significant advantages, such as, for example, but not limited to, controlling the wavelength and the intensity of the LEDs and tuning the LEDs into specific bins, thereby reducing the number of bins.

The present invention is also directed to a method for matching light output of a first lighting system and a second lighting system, comprising the steps of: (a) providing a first lighting system having a light output, said first lighting system comprising: (1) a light emitting diode (LED) package; (2) at least one light emitting diode (LED) chip associated with the light emitting diode (LED) package; and (3) a phosphor material associated with at least a portion of the at least one light emitting diode (LED) chip; (b) determining the light output of the first lighting system and establishing binning parameters; (c) providing a second lighting system having a light output, said second lighting system comprising: (1) a light emitting diode (LED) package; (2) at least one light emitting diode (LED) chip associated with the light emitting diode (LED) package; and (3) a phosphor material associated with at least a portion of the at least one light emitting diode (LED) chip, wherein the phosphor material comprises: (a) a first converting material, wherein the first converting material emits in the visible light spectrum; and (b) a second converting material, wherein the second converting material emits in the non-visible light spectrum; and (d) substantially matching the light output of the second lighting system to the light output of the first lighting system via the first and second converting materials of the second lighting system to comport with the established binning parameters.

The foregoing description merely explains and illustrates the invention and the invention is not limited thereto except insofar as the appended claims are so limited, as those skilled in the art who have the disclosure before them will be able to make modifications without departing from the scope of the invention.

While certain embodiments have been illustrated and described, it should be understood that changes and modifications can be made therein in accordance with ordinary skill in the art without departing from the technology in its broader aspects as defined in the following claims.

The embodiments, illustratively described herein may suitably be practiced in the absence of any element or elements, limitation or limitations, not specifically disclosed herein. Thus, for example, the terms “comprising,” “including,” “containing,” etcetera shall be read expansively and without limitation. Additionally, the terms and expressions employed herein have been used as terms of description and not of limitation, and there is no intention in the use of such terms and expressions of excluding any equivalents of the features shown and described or portions thereof, but it is recognized that various modifications are possible within the scope of the claimed technology. Additionally, the phrase “consisting essentially of” will be understood to include those elements specifically recited and those additional elements that do not materially affect the basic and novel characteristics of the claimed technology. The phrase “consisting of” excludes any element not specified.

The present disclosure is not to be limited in terms of the particular embodiments described in this application. Many modifications and variations can be made without departing from its spirit and scope, as will be apparent to those skilled in the art. Functionally equivalent methods and compositions within the scope of the disclosure, in addition to those enumerated herein, will be apparent to those skilled in the art from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, reagents, compounds compositions or biological systems, which can of course vary. It is also to be understood that the terminology used herein is for the purpose of describing particular embodiments only, and is not intended to be limiting.

In addition, where features or aspects of the disclosure are described in terms of Markush groups, those skilled in the art will recognize that the disclosure is also thereby described in terms of any individual member or subgroup of members of the Markush group.

As will be understood by one skilled in the art, for any and all purposes, particularly in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etcetera. As a non-limiting example, each range discussed herein can be readily broken down into a lower third, middle third and upper third, etcetera. As will also be understood by one skilled in the art all language such as “up to,” “at least,” “greater than,” “less than,” and the like, include the number recited and refer to ranges which can be subsequently broken down into subranges as discussed above. Finally, as will be understood by one skilled in the art, a range includes each individual member.

All publications, patent applications, issued patents, and other documents referred to in this specification are herein incorporated by reference as if each individual publication, patent application, issued patent, or other document was specifically and individually indicated to be incorporated by reference in its entirety. Definitions that are contained in text incorporated by reference are excluded to the extent that they contradict definitions in this disclosure.

Other embodiments are set forth in the following claims.

What is claimed and desired to be secured by Letters Patent of the United States is:

1. A lighting system combining visible and non-visible light converting phosphor, said lighting system comprising:
a light emitting diode (LED) package;
at least one light emitting diode (LED) chip associated with the light emitting diode (LED) package;
a phosphor material associated with at least a portion of the at least one light emitting diode (LED) chip, wherein the phosphor material comprises:
a first converting material, wherein the first converting material emits in the visible light spectrum;
a second converting material, wherein the second converting material emits in the non-visible light spectrum; and
wherein the first converting material and the second converting material controllably regulate light output of the lighting system.

2. The lighting system according to claim 1, wherein the first converting material comprises yttrium aluminum garnet.

3. The lighting system according to claim 2, wherein the first converting material comprises yttrium aluminum garnet doped with at least one of the group consisting of an alkali metal, an alkaline earth metal, a transition metal, a lanthanide, an actinide, and combinations thereof.

4. The lighting system according to claim 1, wherein the first converting material comprises lutetium aluminum garnet.

5. The lighting system according to claim 4, wherein the first converting material comprises yttrium aluminum garnet doped with at least one of the group consisting of an alkali metal, an alkaline earth metal, a transition metal, a lanthanide, an actinide, and combinations thereof.

6. The lighting system according to claim 1, wherein the first converting material comprises a nitride.

7. The lighting system according to claim 6, wherein the nitride comprises an interstitial nitride, gallium nitride, and/or indium gallium nitride.

8. The lighting system according to claim 1, wherein the first converting material comprises a silicate.

9. The lighting system according to claim 8, wherein the silicate comprises a europium doped silicate.

10. The lighting system according to claim 1, wherein the first converting material is selected from at least one of the group consisting of yttrium aluminum garnet, yttrium gallium garnet, lutetium aluminum garnet, lutetium gallium garnet, nitride, silicate, and combinations thereof.

11. The lighting system according to claim 1, wherein the second converting material comprises gadolinium gallium aluminum garnet.

12. The lighting system according to claim 1, wherein the second converting material comprises oxo(oxochromiooxy)chromium.

13. The lighting system according to claim 1, wherein the second converting material comprises chromium(III) oxide.

14. The lighting system according to claim 1, wherein the second converting material comprises gadolinium gallium aluminum garnet and chromium(III) oxide.

15. The lighting system according to claim 14, wherein the weight ratio of gadolinium gallium aluminum garnet to chromium(III) oxide ranges from approximately 99:1 to approximately 90:10.

16. The lighting system according to claim 15, wherein the ratio of Al³⁺ to Ga³⁺ in the gadolinium gallium aluminum garnet ranges from approximately 0.25:1 to approximately 0.95:1.

17. The lighting system according to claim 15, wherein the ratio of Al³⁺ to Ga³⁺ in the gadolinium gallium aluminum garnet ranges from approximately 0.5:1 to approximately 0.7:1.

18. The lighting system according to claim 1, wherein the at least one light emitting diode (LED) chip is a blue LED chip and/or a UV LED chip.

19. A method for matching light output of a first lighting system and a second lighting system, comprising the steps of:
providing a first lighting system having a light output, said first lighting system comprising:
a light emitting diode (LED) package;
at least one light emitting diode (LED) chip associated with the light emitting diode (LED) package; and
a phosphor material associated with at least a portion of the at least one light emitting diode (LED) chip;
determining the light output of the first lighting system and establishing binning parameters;
providing a second lighting system having a light output, said second lighting system comprising:
a light emitting diode (LED) package;
at least one light emitting diode (LED) chip associated with the light emitting diode (LED) package; and
a phosphor material associated with at least a portion of the at least one light emitting diode (LED) chip, wherein the phosphor material comprises:
a first converting material, wherein the first converting material emits in the visible light spectrum; and
a second converting material, wherein the second converting material emits in the non-visible light spectrum; and
substantially matching the light output of the second lighting system to the light output of the first lighting system via the first and second converting materials of the second lighting system to comport with the established binning parameters.
